(19) United States
(12) Patent Application Publication
(10) Pub. No.: US 2007/0241400 A1
(43) Pub. Date: Oct. 18, 2007

(54) SEMICONDUCTOR DEVICE

(75) Inventor: Ryo NAGAI, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: Elpida Memory, Inc., Tokyo (JP)

(21) Appl. No.: 11/733,010

(22) Filed: Apr. 9, 2007

(30) Foreign Application Priority Data
Apr. 12, 2006 (JP) 2006-109881

(51) Int. Cl. H01L 27/12

(52) U.S. Cl. 257/347

(57) ABSTRACT

A high performance semiconductor device has an NMOS and a PMOS for which each channel is formed on an optimal crystal plane. A semiconductor device comprises a silicon single-crystal substrate whose surface is a (110) crystal plane, a PMOSFET formed on a (110) plane as a wall surface of a Fin perpendicular to a <110> axis, and an NMOSFET formed on a (001) plane as a wall surface of a Fin perpendicular to a <001> axis on the (110) plane of the substrate.

### FIELD OF THE INVENTION

This invention relates to a semiconductor device, and particularly relates to a semiconductor device preferably used for a FinFET, and the like.

### BACKGROUND OF THE INVENTION

A recent development of a MOSLSI technology requires a MOS transistor as a basic element of the MOSLSI technology to increase its capability beyond which is obtained by a miniaturization of the device. For example, efforts have been made to introduce strain in a silicon crystal to increase mobility of carriers and the like.

Nowadays according to the CMOS technology as a main MOSLSI technology, both an NMOS and a PMOS, which constitute the CMOS technology, are formed on the same substrate and the same (100) crystal plane in general. The (100) crystal plane is a plane that shows the highest mobility of electrons, that is, a carrier of the NMOS. However, the (100) crystal plane is not the best plane for the PMOS because a (110) crystal plane is the best plane to obtain the highest mobility of holes, that is, a carrier of the PMOS.

As for miniaturization, it is considered difficult to realize a fine-structured transistor whose gate length is less than or equal to 40 nm because it is difficult to avoid occurrence of the short channel effect when using a conventional planar-type MOS transistor. On the other hand, a FinFET is expected to be prospective in a fine-structure region less than or equal to 40 nm because it has a resistance against the short channel effect and can be easily implemented in the fine-structured transistor.

Patent Document 1 discloses a semiconductor device using a (100) plane for an n-channel FET and a (110) plane for a p-channel FET. That is, a complementary semiconductor device having a vertical n-channel FET formed on a side-wall surface, which has a (100) crystal plane, of a trench on a silicon substrate and a vertical p-channel FET formed on a side-wall surface, which has a (110) crystal plane, of a trench on the silicon substrate is disclosed. This structure is similar to a FinFET from a viewpoint that the wall surface is utilized as a conductive channel, however, the basic structure of the transistor is a planar-type which is merely arranged in a vertical direction. Therefore current flows vertically and source and drain are located at upper side and lower side.

[Patent Document 1]

JP Patent Kokai Publication No. JP-63-80562A

[Patent Document 2]

JP Patent Kokai Publication No. JP-P2005-19996A

### SUMMARY OF THE DISCLOSURE

In the following analyses are given by the present invention on the related art. The disclosures of aforementioned Patent Documents are incorporated herein by reference thereto.

Each carrier among electrons as a conductive carrier of NMOS and holes as a conductive carrier of PMOS has a specific crystal plane that gives the highest mobility as described above. Therefore, the different, specific crystal planes showing the highest mobility of carriers for each NMOS and PMOS should be used to obtain a transistor having a higher drive-current capability. When a combination of NMOS and PMOS with optimal crystal planes as conductive channels would be formed on the same silicon substrate, a CMOS circuit having a higher capability could be realized. However, an NMOS and a PMOS constituting a CMOS are formed on the same crystal plane conventionally. And it is considered to be difficult to avoid occurrence of the short channel effect of a conventional planar-type MOS transistor and to fabricate a fine-structured transistor having a gate length of less than 40 nm or equal.

Instead, a FinFET having less short channel effect is expected as a fine-structured transistor.

As for an integrated semiconductor circuit having an n-channel FinFET or a p-channel FinFET, Patent Document 2 discloses an integrated semiconductor circuit having a combination of a p-FinFET whose structure has a (110) surface orientation and a conventional n-FET, not a Fin-type, whose structure has a (100) surface orientation. Also there is disclosed another combination of an n-FinFET having a (100) surface orientation and a conventional p-FET having a (110) surface orientation.

However, according to the related art, it is not possible to provide a high-performance integrated semiconductor circuit having a combination of a p-FinFET and an n-FinFET, particularly based on the SOI structure.

Accordingly it is an object of the present invention to provide an enhanced performance semiconductor device having an NMOS and a PMOS for which each channel is formed on an optimal crystal plane.

The present invention comprises structures undermentioned in general, in order to eliminate problems afore-mentioned.

According to a first aspect of the present invention, there is provided a semiconductor device comprising: a p-channel FinFET on a (110) plane as a wall surface perpendicular to a <110> axis and an n-channel FinFET on a (001) plane as a wall surface perpendicular to a <001> axis; wherein the p-channel FinFET and the n-channel FinFET are disposed on a (110) plane.

According to a second aspect of the present invention, there is provided a semiconductor device comprising: a substrate having a (110) surface; a wall-shaped silicon single-crystal layer disposed on the substrate; a p-channel FinFET and a n-channel FinFET disposed on the (110) surface of the substrate; wherein the p-channel FinFET is disposed on a (110) plane as a wall surface perpendicular to a <110> axis, and the n-channel FinFET is disposed on a (001) plane as a wall surface perpendicular to a <001> axis.

According to a third aspect of the present invention, a gate electrode with an intervened gate oxide film extends in each of the directions of the <110> axis and the <001> axis respectively, along the wall surfaces on which the p-channel FinFET and the n-channel FinFET are formed; and channels are formed along both surfaces of the wall surfaces.

According to a fourth aspect of the present invention, a planar construction of the wall-shaped silicon single-crystal layer is formed such that each of the p-channel FinFET and the n-channel FinFET extends in each of the directions from a contacting point at which both drains of the p-channel FinFET and the n-channel FinFET are connected; each of the FinFETs is connected to corresponding power supply; the gate electrodes are formed to cross each other at respective channel regions of the p-channel FinFET and the n-channel FinFET extended in two directions; and the semiconductor device is constructed as a CMOS circuit.

According to a fifth aspect of the present invention, a semiconductor device comprises: a p-channel FinFET on a (110) plane as a wall surface perpendicular to a <110> axis, and an n-channel FinFET on a (100) plane as a wall surface perpendicular to a <100> axis on a (100) plane, wherein the p-channel FinFET and the n-channel FinFET are disposed on a (100) plane.

According to a sixth aspect of the present invention, the FinFETs are formed on one of a silicon single-crystal layer and a bulk silicon wafer of an SOI (silicon-on-insulator) structure.

According to a seventh aspect of the present invention, a semiconductor device comprises: a p-channel FinFET on a first crystal plane being a first wall surface having a highest carrier mobility among planes of a crystal; an n-channel FinFET on a second crystal plane being a second wall surface having a highest carrier mobility among planes of a crystal; wherein the p-channel FinFET and the n-channel FinFET are disposed on a substrate.

According to an eighth aspect of the present invention, the crystal is a single crystal, and the first and second crystal planes are different crystal planes of the single crystal.

According to a ninth aspect of the present invention, the first and second wall surfaces are formed of wall surfaces of a single crystal, respectively.

According to a tenth aspect of the present invention, the single crystal comprises a single silicon crystal, the first crystal plane comprises a (110) plane, and the second crystal plane comprises a (001) plane.

According to a eleventh aspect of the present invention, the single crystal comprises a single silicon crystal, the first crystal plane comprises a (110) plane, and the second crystal plane comprises (100) plane.

According to a twelfth aspect of the present invention, the single crystal comprises a single silicon crystal, the first crystal plane comprises a (110) or (−110) plane, and the second crystal plane comprises a (100) or (010) plane.

According to a thirteenth aspect of the present invention, the first wall surface and the second wall surface are formed continuous with each other.

According to a fourteenth aspect of the present invention, the first and second walls are formed in a solid single crystal body with a substrate.

According to a fifteenth aspect of the present invention, the first or second crystal plane is formed on first and back surfaces of a wall body of a single crystal.

The meritorious effects of the present invention are summarized as follows.

According to the present invention, the performance of CMOS can be improved by specifically forming an NMOS and a PMOS in which each channel is formed on an optimal crystal plane on the same substrate, based on the FinFET configuration.

### BRIEF DESCRIPTION OF THE DRAWINGS

FIG. 1 shows a perspective view of a structure of an exemplary aspect of the present invention.

FIG. 2 shows a diagram for illustrating a structure of the exemplary aspect of the present invention.

FIG. 3 shows a plan view of FIG. 1.

FIG. 4 shows a fabrication method of the exemplary aspect of the present invention.

FIG. 5 shows a fabrication method of the exemplary aspect of the present invention.

FIG. 6 shows a fabrication method of the exemplary aspect of the present invention.

FIG. 7 shows a diagram for illustrating a structure of a second exemplary aspect of the present invention.

### PREFERRED MODES OF THE INVENTION

Examples of the present invention are described in detail with reference to the drawings. A FinFET according to an example of the present invention is a kind of a MOS-type semiconductor device. Gate electrodes 41 of transistors are formed by depositing a gate insulating film on thin walls (Fin) of silicon single-crystal and wall surfaces of the silicon are used as channels. A construction of a CMOS using the FinFET is characterized in that conductive channels of the transistor are formed on the same substrate such that a channel of an NMOS is formed on a (100) silicon crystal plane and a channel of a PMOS is formed on a (110) silicon crystal plane.

A crystal plane having the highest mobility of electrons is the (100) plane and a crystal plane having the highest mobility of holes is the (110) plane.

When forming a FinFET, walls on a silicon bulk wafer or an SOI wafer having different crystal planes can be obtained by selecting directions of the wall-shaped silicon (Fin) properly. According to the present invention, a wall having the (100) plane for the NMOS and a wall having the (110) plane for the PMOS are utilized in the FinFET for the CMOS.

The present invention differs from Patent Document 1 and both surfaces of the thin silicon wall are used as conductive channels, a source and a drain are disposed on both the sides of the silicon wall with a gate interposed between them, and a current flows laterally (or transverse). The details are described with examples.

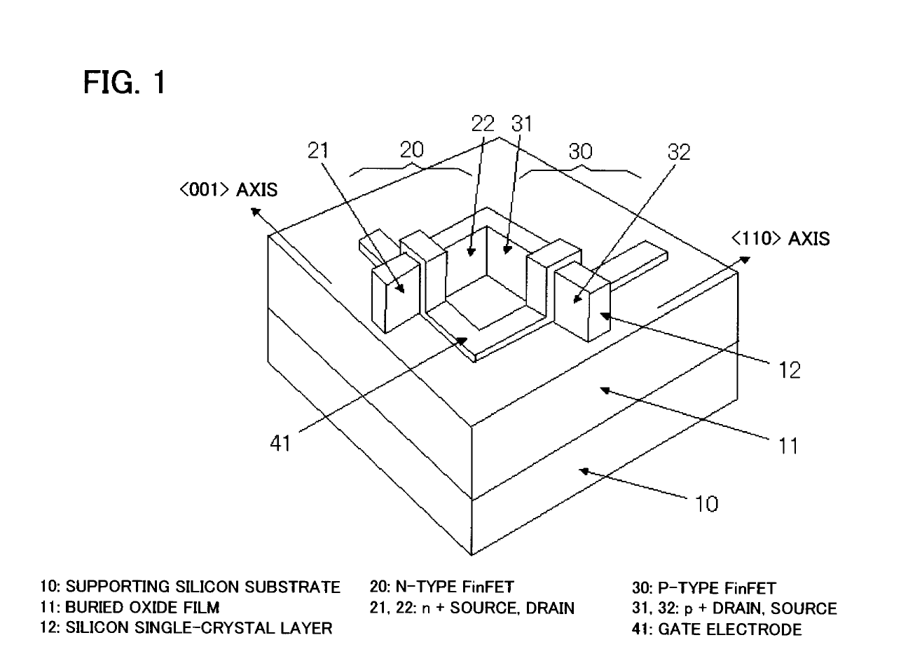

FIG. 1 shows a perspective view of a structure of a Fin-type CMOSFET device fabricated on an SOI (Silicon On Insulator) wafer made of a silicon thin film (silicon single-crystal layer) having a surface of (110) crystal plane according to an example of the present invention. The SOI structure of FIG. 1 comprises a silicon single-crystal layer (also called “SOI layer”) 12 on a surface of a buried oxide film 11 on a supporting silicon substrate (silicon semiconductor layer) 10. The thin wall-shaped silicon single-crystal layer 12 comprises an N-type FinFET 20 formed on a wall surface perpendicular to a <001> axis and a P-type FinFET 30 formed on a wall surface perpendicular to a <110> axis. A gate electrode (layer) 41 extends vertically from the height of the buried oxide film 11 on a front surface of the wall of the SOI layer up to the top, traverses the top of the wall and disposed vertically on a back surface of the wall of the SOI layer down to the surface of the buried oxide film 11. The N-type FinFET 20 comprises n+ source diffusion layer 21 and n+ drain diffusion layer 22 at the both sides of the interposed gate electrode 41. The P-type FinFET 30 comprises p+ source diffusion layer 32 and p+ drain diffusion layer 31 on the both sides of the interposed gate electrode 41. A gate insulating film (not shown) is formed between the gate electrode 41 and the silicon channel just beneath the gate electrode 41. The n+ drain diffusion layer 22 of the N-type FinFET 20 and the p+ drain diffusion layer 31 of the P-type FinFET 30 are in contact at an angle of 90 degrees.

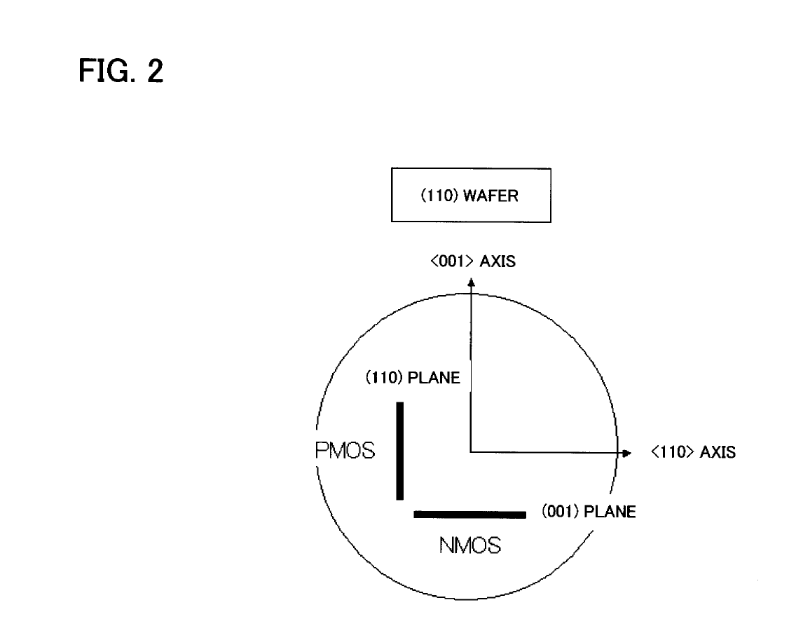

FIG. 2 shows a diagram for illustrating a planar structure of the transistor shown in FIG. 1. Plane directions in FIG. 2 indicate that each plane includes each line and extends perpendicular to the wafer plane (paper sheet surface). There are <110> crystal axis and <001> crystal axis on the (110) plane and they make an angle of 90 degrees as shown in FIG. 2. When a Fin perpendicular to the <110> crystal axis is formed, the wall surface of the Fin is the (110) plane and a PMOSFET is formed on the wall. Similarly, when a Fin perpendicular to the <001> crystal axis is formed, the wall surface of the Fin is the (001) plane (equivalent to a (100) plane) and an NMOSFET is formed, finally resulting in a CMOS inverter circuit.

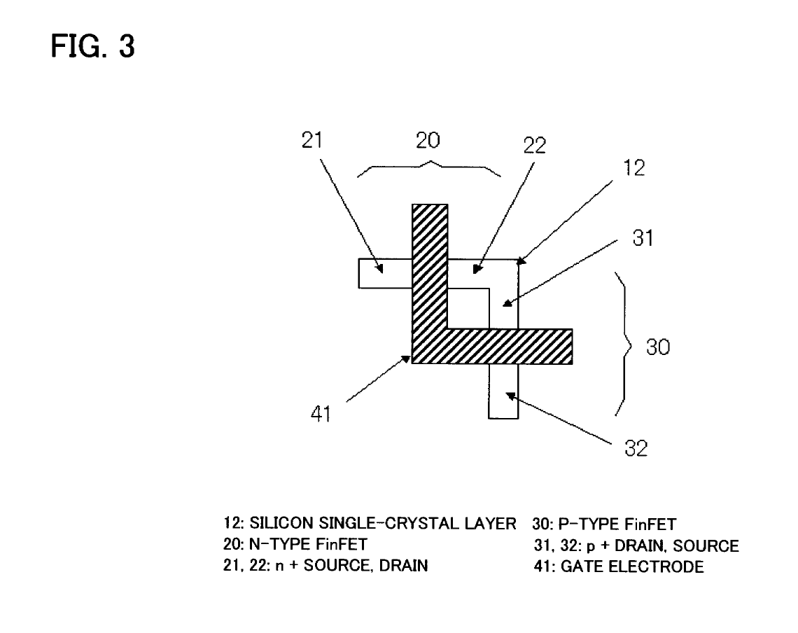

FIG. 3 shows a plan view of the Fin-type CMOSFET shown in FIG. 1. Each wall surface of the n-channel (n-type) FinFET 20 and the p-channel (p-type) FinFET 30 corresponds to the (100) plane and the (110) plane, respectively in FIG. 1. In FIG. 3, reference numeral 12 denotes the silicon single-crystal layer, whereas reference numeral 41 denotes the gate electrode layer. Also, reference numerals 20 and 30 denote the n-channel FinFET and the p-channel FinFET, respectively.

An inverter circuit can be obtained by connecting the source diffusion layer 32 of the p-channel FinFET to a power supply voltage, the source diffusion layer 21 of the n-channel FinFET to the ground, the n+ drain diffusion layer 22 electrically connected with the p+ drain diffusion layer 31 to an output terminal, and the gate electrode 41 to an input terminal, respectively.

According to an example described above, the channel of the n-channel FinFET is formed in the (100) crystal plane and the channel of the p-channel FinFET is formed in the (110) crystal plane and the transistor has the maximum mobility of each carriers. Thus a CMOS circuit with a higher performance can be achieved.

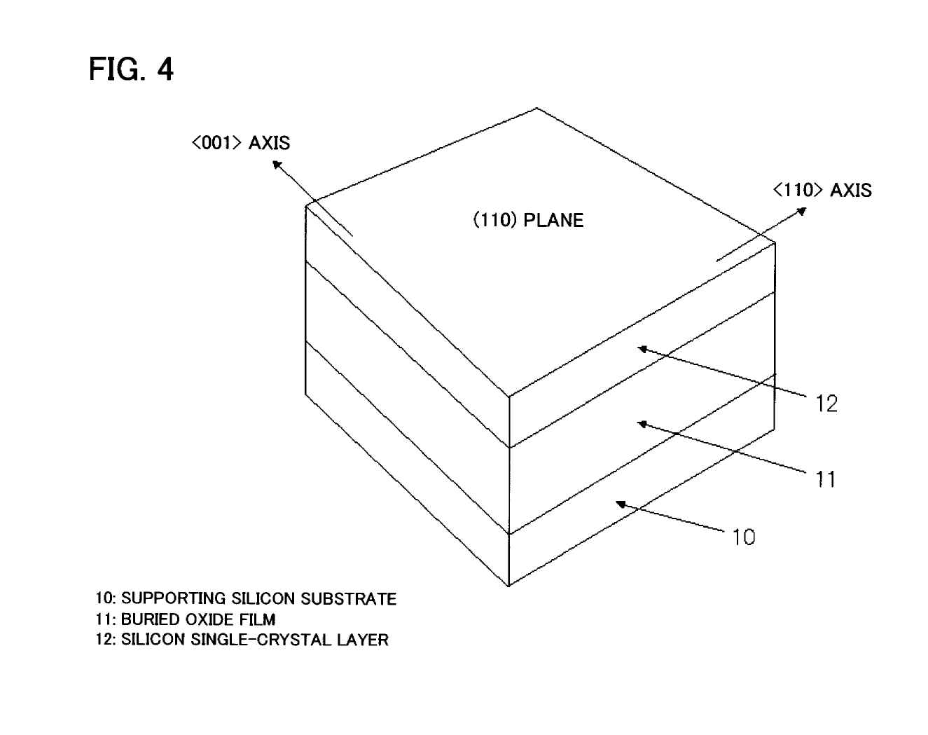

Next a fabrication method of the exemplary device of the present invention is described with reference to FIG. 4 to 6.

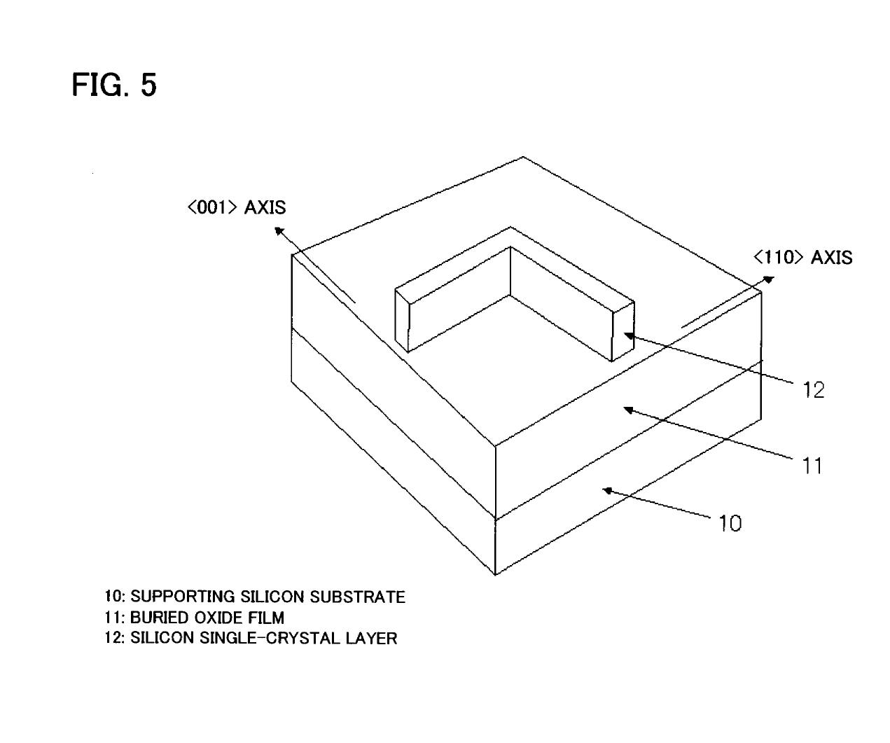

At first, an SOI substrate (see FIG. 4) with a thin film silicon layer (silicon single-crystal layer 12 in FIG. 4) whose surface is a (110) crystal plane is prepared. Then a silicon single-crystal 12 is formed utilizing known lithography and etching techniques as shown in FIG. 5.

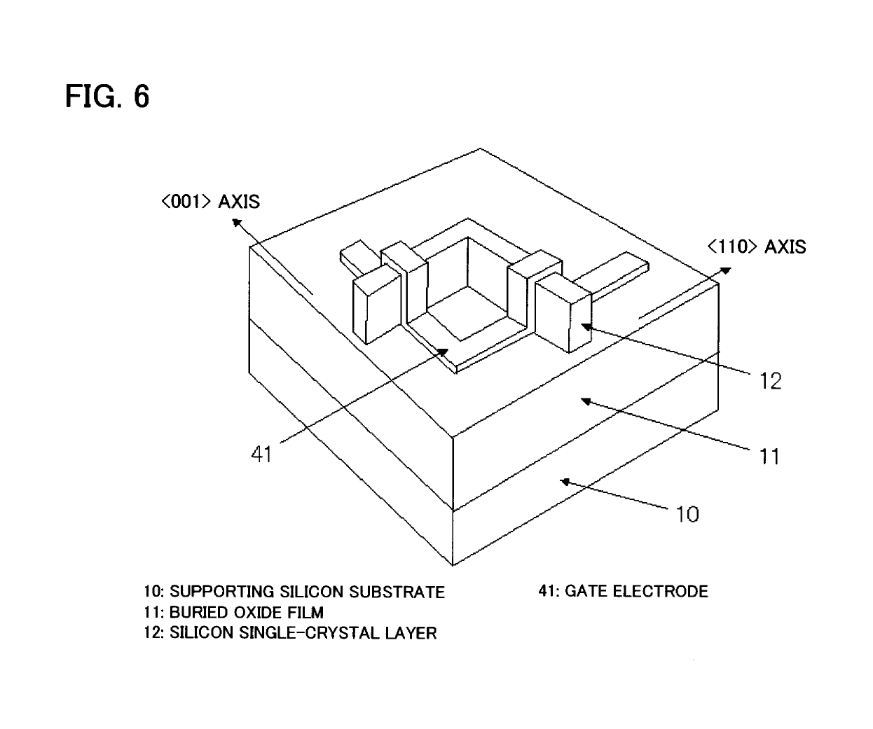

Next the gate insulating film (not shown) is formed utilizing known techniques as oxidation or CVD (Chemical Vapor Deposition), etc., and then a gate electrode material is deposited and etched into a predetermined shape utilizing known lithography and etching techniques (see FIG. 6).

Next the diffusion layers of both transistors are formed by the steps of photolithography, ion implantation and annealing, etc., and the structure shown in FIG. 1 is obtained.

Finally, a semiconductor device is completed by depositing interlayer insulating films, forming of connection holes (vias) and metal wirings (traces), etc., (none is shown) as necessary.

The channel of the n-channel FinFET is formed on the (001) crystal plane, and the channel of the p-channel FinFET is formed on the (110) crystal plane resulting in a transistor having the maximum mobility of each carrier. Thus a CMOS circuit with an enhanced performance can be achieved.

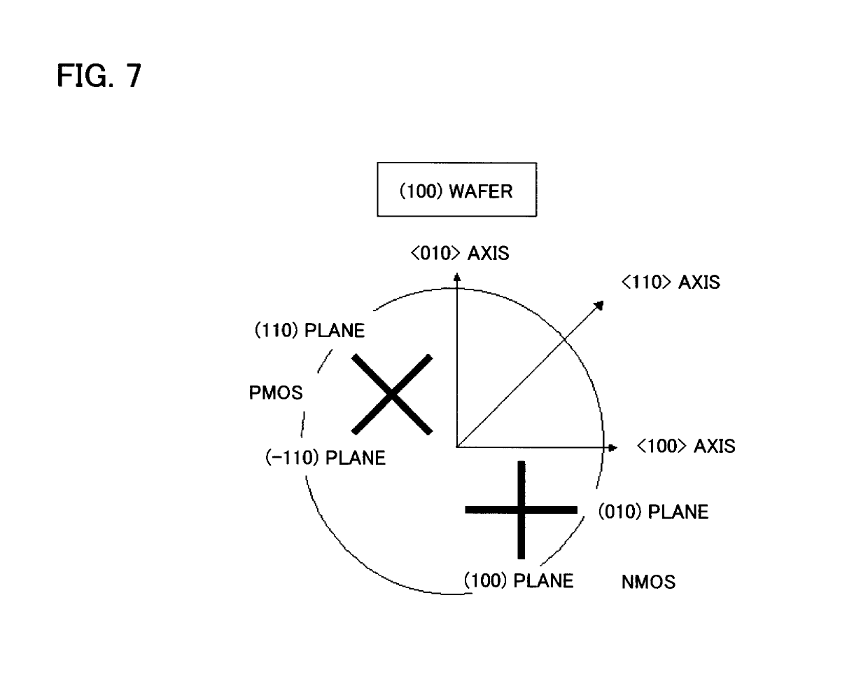

FIG. 7 shows a diagram for illustrating a structure of a second example of the present invention. Plane directions in FIG. 7 indicate that each planes includes each line and extends perpendicular to the wafer plane (paper sheet surface). The SOI substrate used in this example has a silicon single-crystal thin film whose surface is a (100) crystal plane.

There are a <100> crystal axis and a <110> crystal axis on the (100) plane, and they make an angle of 45 or 135 degrees.

When a Fin perpendicular to the <100> crystal axis is formed, the wall surface of the Fin is the (100) plane and the n-channel FinFET is formed on the wall.

When a Fin perpendicular to the <110> crystal axis is formed, the wall surface of the Fin is the (110) plane, and the p-channel FinFET is formed on the wall. Thus a CMOS circuit with an enhanced performance can be also achieved by this structure likewise a first example. As shown in FIG. 1 or FIG. 6, the (110) crystal plane or the (001) crystal plane may be formed on both sides (front and back wall surfaces) of a wall body so that the wall surface area is utilized more efficiently at a lower wall height. The same is applicable for the (110) or (−110) plane and the (010) or (100) plane as shown in FIG. 7.

Note, a (−110) plane is equivalent to the (110) plane for PMOS and a (010) plane is equivalent to the (100) plane for NMOS.

The exemplary aspects of the present invention have been explained using SOI wafers, however, the same effects will be obtained by using bulk silicon wafers. The present invention realizing an enhanced performance CMOS is preferably adapted to CMOS devices for high performance MPU, and so on.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor device comprising:
a p-channel FinFET on a (110) plane as a wall surface perpendicular to a <110> axis; and
an n-channel FinFET on a (001) plane as a wall surface perpendicular to a <001> axis;
wherein said p-channel FinFET and said n-channel FinFET are disposed on a (110) plane.

2. A semiconductor device comprising:
a substrate having a (110) surface;
a wall-shaped silicon single-crystal layer disposed on said substrate;
a p-channel FinFET and a n-channel FinFET disposed on said (110) surface of the substrate;
wherein said p-channel FinFET is disposed on a (110) plane as a wall surface perpendicular to a <110> axis, and said n-channel FinFET is disposed on a (001) plane as a wall surface perpendicular to a <001> axis.

3. The semiconductor device as defined in claim 2, wherein
a gate electrode with an intervened gate oxide film extends in each of the directions of said <110> axis and said <001> axis respectively, along said wall surfaces on which said p-channel FinFET and said n-channel FinFET are formed; and
channels are formed along both surfaces of said wall surfaces.

4. The semiconductor device as defined in claim 3, wherein
a planar construction of said wall-shaped silicon single-crystal layer is formed such that each of said p-channel FinFET and said n-channel FinFET extends in each of said directions from a contacting point at which both drains of said p-channel FinFET and said n-channel FinFET are connected,
each of said FinFETs being connected to corresponding power supply;
said gate electrodes being formed to cross each other at respective channel regions of said p-channel FinFET and said n-channel FinFET extended in two directions; and
said semiconductor device being constructed as a CMOS circuit.

5. A semiconductor device comprising:
a p-channel FinFET on a (110) plane as a wall surface perpendicular to a <110> axis; and
an n-channel FinFET on a (100) plane as a wall surface perpendicular to a <100> axis;
wherein said p-channel FinFET and said n-channel FinFET are disposed on a (100) plane.

6. The semiconductor device as defined in claim 1, wherein said FinFETs are formed on one of a silicon single-crystal layer and a bulk silicon wafer of an SOI (silicon-on-insulator) structure.

7. The semiconductor device as defined in claim 2, wherein said FinFETs are formed on one of a silicon single-crystal layer and a bulk silicon wafer of an SOI (silicon-on-insulator) structure.

8. The semiconductor device as defined in claim 5, wherein said FinFETs are formed on one of a silicon single-crystal layer and a bulk silicon wafer of an SOI (silicon-on-insulator) structure.

9. A semiconductor device comprising:
a p-channel FinFET on a first crystal plane being a first wall surface having a highest carrier mobility among planes of a crystal;
an n-channel FinFET on a second crystal plane being a second wall surface having a highest carrier mobility among planes of a crystal;
wherein said p-channel FinFET and said n-channel FinFET are disposed on a substrate.

10. The semiconductor device as defined in claim 9, wherein said crystal is a single crystal, and said first and second crystal planes are different crystal planes of said single crystal.

11. The semiconductor device as defined in claim 9, wherein said first and second wall surfaces are formed of wall surfaces of a single crystal, respectively.

12. The semiconductor device as defined in claim 9, wherein said single crystal comprises a single silicon crystal, said first crystal plane comprises a (110) plane, and said second crystal plane comprises a (001) plane.

13. The semiconductor device as defined in claim 9, wherein said single crystal comprises a single silicon crystal, said first crystal plane comprises a (110) plane, and said second crystal plane comprises (100) plane.

14. The semiconductor device as defined in claim 9, wherein said single crystal comprises a single silicon crystal, said first crystal plane comprises a (110) or (−110) plane, and said second crystal plane comprises a (100) or (010) plane.

15. The semiconductor device as defined in claim 9, wherein said first wall surface and said second wall surface are formed continuous with each other.

16. The semiconductor device as defined in claim 9, wherein said first and second walls are formed in a solid single crystal body with a substrate.

17. The semiconductor device as defined in claim 9, wherein said first or second crystal plane is formed on a front wall surface and a back wall surface of a wall body formed of a single crystal.

18. The semiconductor device as defined in claim 1, wherein said (110) plane or said (001) plane is formed on front and back wall surfaces of a wall body formed of a single crystal.
